(19) United States
(12) Patent Application Publication
(10) Pub. No.: US 2020/0255972 A1
(43) Pub. Date: Aug. 13, 2020

(54) METHOD, DEVICE, SYSTEM, AND COMPUTER STORAGE MEDIUM FOR CRYSTAL GROWING CONTROL

(71) Applicant: ZING SEMICONDUCTOR CORPORATION, Shanghai (CN)

(72) Inventor: Xianliang Deng, Shanghai (CN)

(21) Appl. No.: 16/664,357

(22) Filed: Oct. 25, 2019

(30) Foreign Application Priority Data
Oct. 29, 2018 (CN) 201811272682.6

(51) Int. Cl. C30B 15/22; C30B 29/06

(52) U.S. Cl. CPC C30B 15/22; C30B 29/06

(57) ABSTRACT

This invention provides method, device, system, and computer storage medium for crystal growth control of a shouldering process. The method comprises: presetting a setting value of a crystal diameter variation at different stages of a shouldering process and a setting value of a crystal growth process parameter at different stages of the shouldering process; obtaining crystal diameters at different stages of the shouldering process and calculating a measured crystal diameter variation; comparing the measured crystal diameter variation with the setting value of the crystal diameter variation to obtain a difference as an input variable of PID algorithm; calculating an adjustment value of a crystal growth process parameter by PID algorithm as an output variable of PID algorithm; adding the adjustment value of the crystal growth process parameter and the setting value of the crystal growth process parameter to obtain a process parameter of an actual crystal growth process. The method, device, system, and computer storage medium control the crystal diameter variation during the shouldering process by PID algorithm to overcome an influence of small changes in the thermal field to the shouldering process, ensure the crystal diameter variation is consistent, and improve the repeatability of the shouldering process and the stability of the process.

### CROSS-REFERENCE TO RELATED APPLICATIONS

This application claims priority to P.R.C. Patent Application No. 201811272682.6 titled “method, device, system, and computer storage medium for crystal growing control,” filed on Oct. 29, 2018, with the State Intellectual Property Office of the People's Republic of China (SIPO).

### TECHNICAL FIELD

The present disclosure relates to method, device, system, and computer storage medium for crystal growing control, and particularly, to method, device, system, and computer storage medium for crystal growth control of a shouldering process.

### BACKGROUND

The monocrystalline silicon is generally used as a semiconductor material for manufacturing an integrated circuit and other electronic component. During the process of preparing the monocrystalline silicon, a seed crystal having small diameter is immersed in the melt of silicon, and then a segment of fine-grained crystal having small diameter is grown by crystal seeding to reach the goal of zero dislocation crystal growth. The crystal is grown from fine-grained crystal to the crystal with target diameter through a shouldering process, and the crystal is obtained with required size through an equal diameter growth.

The shouldering process is a key process in the crystal growth, which is the basic of obtaining the crystal with the target diameter. Currently, the main method is used to increase the crystal diameter to achieve the target diameter by combining reducing crystal pulling speed and reducing temperature. The change of crystal pulling speed and temperature is determined by shouldering starting time or shouldering length during shouldering process, therefore it is necessary to match the crystal pulling speed and temperature at different stages in the shouldering process. However, there are some difference in the thermal field using time, the crystal seeding temperature and the heater life during actual crystal growth each time, the crystal structure will be lost if the temperature and the crystal pulling speed setting cannot be adjusted immediately. Moreover, the change of different crystal growth conditions will also lead different shouldering process, such that the shouldering process is the most difficult part of the develop process of the crystal growth process, and many attempts should be required to find suitable temperature and pulling speed settings. It is also the most difficult part of the crystal growth process to achieve uniformity every time of the shouldering process.

Based on the above, it is necessary to provide method, device and system and computer storage medium for the crystal growth control of the shouldering process.

### SUMMARY

A series of simplified forms of concepts are introduced in the Summary of the Invention section, which will be described in further detail in the Detailed Description section. The summary of the invention is not intended to limit the key features and essential technical features of the claimed invention, and is not intended to limit the scope of protection of the claimed embodiments.

An objective of the present invention is to provide a method for crystal growth control of a shouldering process. The method comprises: presetting a setting value of a crystal diameter variation at different stages of a shouldering process and a setting value of a crystal growth process parameter at different stages of the shouldering process; obtaining crystal diameters at different stages of the shouldering process and calculating a measured crystal diameter variation; comparing the measured crystal diameter with the setting value of the crystal diameter variation to obtain a difference as an input variable of PID algorithm (Proportional-Integral-Derivative algorithm); calculating an adjustment value of a crystal growth process parameter by PID algorithm as an output variable of PID algorithm; and adding the adjustment value of the crystal growth process parameter and the setting value of the crystal growth process parameter to obtain a process parameter of an actual crystal growth process, so as to ensure consistency of the crystal diameter variation and ensure the stability of crystal growth quality from different lots.

In accordance with some embodiments, the crystal growth process parameter of the shouldering process comprises a crystal pulling speed and/or a temperature.

In accordance with some embodiments, the different stages of the shouldering process comprise a different shouldering time.

In accordance with some embodiments, the different stages of the shouldering process comprise a different crystal length.

In accordance with some embodiments, the crystal diameter at different stages of the shouldering process is obtained by a diameter measuring device.

Another objective of the present invention is to provide a device for crystal growth control of a shouldering process. The device comprises a presetting unit for presetting a setting value of a crystal diameter variation at different stages of a shouldering process and a setting value of a crystal growth process parameter at different stages of the shouldering process; a diameter measuring device for obtaining crystal diameters at different stages of the shouldering process and calculating a measured crystal diameter variation; a comparing unit for comparing measured crystal diameter variation with the setting value of the crystal diameter variation to obtain a difference; a PID controlling unit for taking the difference as an input variable of the PID controlling unit and calculating an adjustment value of a crystal growth process parameter by PID algorithm as an output variable of the PID controlling unit; and a process parameter setting unit for adding the adjustment value of the crystal growth process parameter and the setting value of the crystal growth process parameter to obtain a process parameter of an actual crystal growth process.

In accordance with some embodiments, the crystal growth process parameter of the shouldering process comprises a crystal pulling speed and/or a crystal pulling temperature.

In accordance with some embodiments, the different stages of the shouldering process comprise a different shouldering time or a different crystal length.

Another objective of the present invention is to provide a system for crystal growth control of a shouldering process. The system comprises a memory, a processor and a computer program stored on the memory and operated on the processor, wherein the processor executes the steps of above mentioned method when operating the computer program.

Another objective of the present invention is to provide a computer storage medium, storing a computer program, wherein the computer storage medium executes the steps of above mentioned method when operating the computer program.

As described above, the method, device and system and computer storage medium for crystal growth control of the shouldering process can control the crystal diameter change of the shouldering process by PID algorithm, and control the crystal diameter change of the shouldering process by fine-turning the crystal growth process parameter to overcome an influence of small changes in the thermal field to the shouldering process, such that the repeatability of the crystal shape and shoulder shape for each growth is high to ensure the crystal diameter variation is consistent. Therefore, the repeatability of the shouldering process and the stability of the process are improve to establish the basis for the stability and the repeatability of the entire crystal growth process, so that the crystal quality of each growth is consistent.

### BRIEF DESCRIPTION OF THE DRAWINGS

Exemplary embodiments will be more readily understood from the following detailed description when read in conjunction with the appended drawings, in which:

FIG. 1 depicts a schematic view of a crystal growth furnace used in the method for crystal growth control according to some embodiments of the present disclosure;

FIG. 2 depicts a schematic view of a monocrystalline silicon ingot obtained from the method for crystal growth control according to some embodiments of the present disclosure;

FIG. 3 depicts a flow diagram of the main process of the method for crystal growth control of the shouldering process according to some embodiments of the present disclosure;

FIG. 4 depicts a schematic view of the method for crystal growth control of the shouldering process according to some embodiments of the present disclosure.

FIG. 5 depicts a schematic view of the device for crystal growth control of the shouldering process according to some embodiments of the present disclosure.

FIG. 6 depicts a schematic block diagram of a system for crystal growth control of the shouldering process according to some embodiments of the present disclosure.

### DETAILED DESCRIPTION

The embodiments of the present invention are described below by way of specific examples, and those skilled in the art can readily understand other advantages and effects of the present invention from the disclosure of the present disclosure. The present invention may be embodied or applied in various other specific embodiments, and various modifications and changes can be made without departing from the spirit and scope of the invention.

In the following description, while the invention will be described in conjunction with various embodiments, it will be understood that these various embodiments are not intended to limit the invention. On the contrary, the invention is intended to cover alternatives, modifications and equivalents, which may be comprised within the scope of the invention as construed according to the Claims. Furthermore, in the following detailed description of various embodiments in accordance with the invention, numerous specific details are set forth in order to provide a thorough understanding of the invention. However, it will be evident to one of ordinary skill in the art that the invention may be practiced without these specific details or with equivalents thereof. In other instances, well known methods, procedures, components, and circuits have not been described in detail as not to unnecessarily obscure aspects of the invention.

To understand the invention thoroughly, the following descriptions will provide detail steps to explain a method for crystal growth control of a shouldering process according to the invention. It is apparent that the practice of the invention is not limited to the specific details familiar to those skilled in the semiconductor arts. The preferred embodiment is described as follows. However, the invention has further embodiments beyond the detailed description.

The terminology used herein is for the purpose of describing particular embodiments only and is not intended to be limiting of example embodiments. As used herein, the singular forms “a,” “an” and “the” are intended to comprise the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

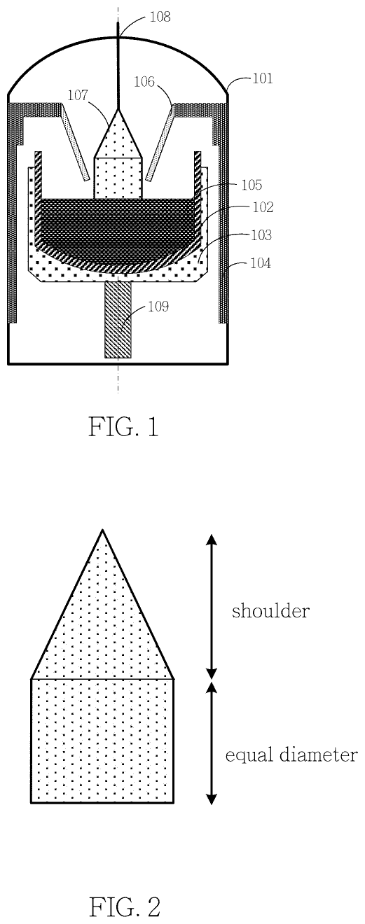

Referring to FIG. 1. FIG. 1 depicts a schematic view of a crystal growth furnace used in the method for crystal growth control according to some embodiments of the present disclosure. As shown in FIG. 1, the crystal growth furnace is configured to grow monocrystalline silicon by Czochralski, which comprises a furnace body 101, where a heating device and a pulling device are arranged in. The heating device comprises a quartz crucible 102, a carbon graphite crucible 103, and a heater 104. The quartz crucible 102 is configured to hold a silicon material, such as polycrystalline silicon. The silicon material is heated therein as a silicon melt 105. The carbon graphite crucible 103 is wrapped around the outside of the quartz crucible 102 to provide the support for the quartz crucible 102 during heating process. The heater 104 is arranged on the outside of the carbon graphite crucible 103. A heat shield 106 is disposed above the quartz crucible 102, and the heat shield 106 has a downwardly conical inverted screen that surrounds the growth region of the monocrystalline silicon 107. The direct heat radiation of the grown monocrystalline silicon ingot 107 from the heater 104 and the high temperature silicon melt 105 can be blocked, and the temperature of the monocrystalline silicon ingot 107 can be lowered. At the same time, the heat shield can also directly spray the protective gas concentrated downward to the vicinity of the growth interface to further enhance the heat dissipation of the monocrystalline silicon ingot 107. An insulating material such as a carbon felt is also provided on the side wall of the furnace body 101.

The pulling device comprises a seed crystal shaft 108 and a crucible shaft 109 vertically disposed. The seed crystal shaft 108 is disposed above the quartz crucible 102. The crucible shaft 109 is disposed at the bottom of the carbon graphite crucible 103. A bottom of the seed crystal shaft 108 is mounted with a seed crystal through a jig, and a top of that is connected to a seed crystal driving device so as to allow it to slowly pull up while rotating. A bottom of the crucible shaft 109 is arranged with a crucible shaft driving device, such that the crucible shaft 109 can drive the crucible to rotate.

When performing monocrystalline growth, first, the silicon material is placed in the quartz crucible 102, then the crystal growth furnace is turned off and vacuumed, and the crystal growth furnace is filled with a protecting gas. For example, the protecting gas is nitrogen, the purity is more than 97%, the pressure is 0.05 Mpa, and the flow rate is 70 L/min. Then the heater 104 is turned on and heated to a melting temperature higher than 1420° C. to completely melt the silicon material into the silicon melt 105 in 20 minutes.

Next, the seed crystal is immersed in the silicon melt 105, and the seed crystal is rotated by the seed crystal shaft 108 and slowly pulled to grow the silicon atom along the seed crystal into a monocrystalline silicon ingot 107. The seed crystal is cut or drilled from a monocrystalline silicon with a certain crystal orientation, and the common crystal orientation is <100>, <111>, <110>, <511>, etc., and the seed crystal is generally a cylinder or a cuboid. The crystal growth process of the monocrystalline silicon ingot 107 comprises the steps of seeding, shouldering, shoulder rotation, equal diameter and closing.

Specifically, the seeding stage is first performed. That is, when the silicon melt 105 is stabilized to a certain temperature, the seed crystal is immersed in the silicon melt, and the seed crystal is lifted at a certain pulling speed, so that the silicon atom grows along the seed crystal into a thin neck with a certain diameter until the thin neck is reached to a predetermined length. The main function of the seeding process is to eliminate the dislocation defects from the monocrystalline silicon caused by the thermal shock. The super cooling degree of the crystal front is used to drive the silicon atoms to be sequentially arranged on the silicon solid of a liquid/solid interface to form a monocrystalline silicon. For example, the pulling speed is from 1.5 mm/min to 2.5 mm/min, the length of the thin neck is 1.2-1.4 times the diameter of the ingot, and the diameter of the thin neck is 5-7 mm.

Next, the shouldering stage is performed. After the thin neck is reached to the predetermined length, the speed of pulling up the seed crystal is slowed down, and the temperature of the silicon melt is slightly lowered. The temperature is lowered to promote the lateral growth of the monocrystalline silicon, even if the diameter of the monocrystalline silicon is increased, the process is referred to as the shouldering stage, as shown in FIG. 2, and the tapered ingot formed at this stage is the shoulder portion of the ingot.

Next, the shoulder rotation stage is performed. When the diameter of the monocrystalline silicon is increased to the target diameter, the temperature of the silicon melt is increased by increasing the heating power of the heater 104, while the speed of pulling up the seed crystal, the speed of rotation, and the rotation speed of the quartz crucible are adjusted for suppressing the lateral growth of the monocrystalline silicon, promoting of longitudinal growth of it, such that the monocrystalline silicon is grown in an almost equal diameter.

Next, the equal diameter stage is performed. When the diameter of the monocrystalline silicon is reached to a predetermined value, the equal diameter stage is performed. As shown in FIG. 2, the cylindrical ingot formed at this stage is an equal diameter section of the ingot. Specifically, the crucible temperature, the crystal pulling speed, the crucible rotation speed, and the crystal rotation speed are adjusted, and the growth rate is stabilized so that the crystal diameter remains unchanged until the completion of the pulling. The equal diameter process is the main stage of the monocrystalline silicon growth, which lasts for several tens of hours or even more than one hundred hours.

Finally, the closing stage is performed. At the closing stage, the rate of increase is increased, and the temperature of the silicon melt 105 is raised to gradually reduce the diameter of the ingot to form a conical shape. When the tip of the cone is small enough, it eventually leaves the liquid level. The finished ingot is lifted to the upper chamber and cooled for a period of time, and then taken out, that is, a growth cycle is completed.

In several stages of the monocrystalline silicon growth process, the shouldering stage is a relatively critical process in the crystal growth process and is the basis for obtaining the target diameter crystal. At present, the main method adopted is to increase the crystal diameter to achieve the target diameter by combining reducing crystal pulling speed and reducing temperature. In the process of shouldering, the change of the pulling speed and the temperature is mainly determined by the starting time of the shouldering or the length of the shouldering. Therefore, it is necessary to match the pulling speed and temperature of different stages in the shouldering process. However, in the actual crystal growth process, there will be some differences in each time of crystal growth due to using time of the heat field, the seeding temperature, the heater life, etc., if the temperature and the crystal pulling speed setting cannot be adjusted immediately, the crystal structure will be lost during the shouldering process. In addition, changes in different crystal growth conditions can also lead to different shouldering processes, which makes the shouldering be the most difficult part of the development process of the crystal growth process. Many attempts are required to find the suitable temperature and crystal pulling speed settings. It is also the most difficult part of the crystal growth process to achieve uniformity every time.

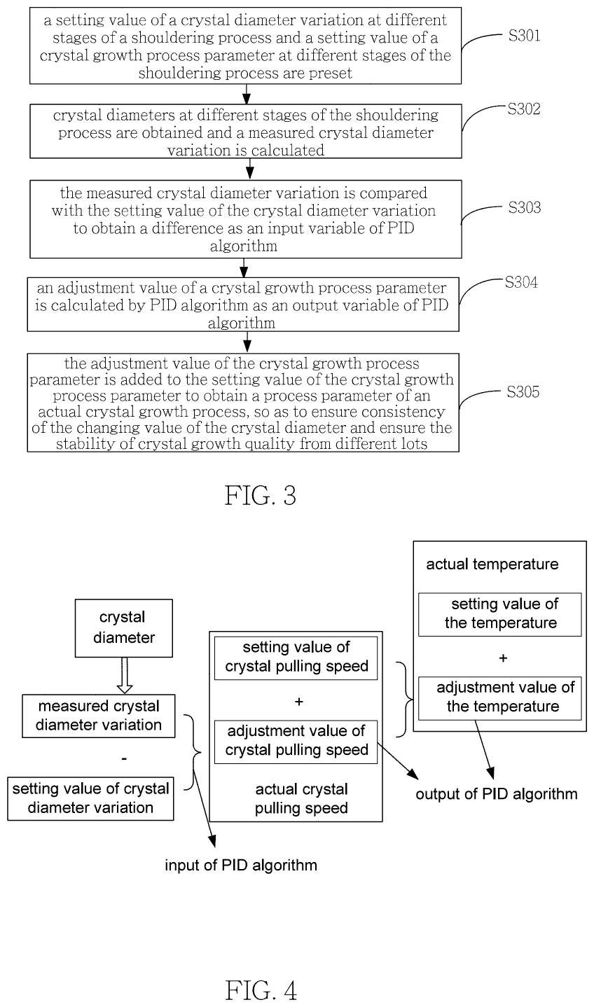

In view of the above problems, the present invention provides a method for crystal growth control of a shouldering process, as shown in FIG. 3, which comprises the following main steps: in the step S301, a setting value of a crystal diameter variation at different stages of a shouldering process and a setting value of a crystal growth process parameter at different stages of the shouldering process are preset;

in the step S302, crystal diameters at different stages of the shouldering process is obtained and a measured crystal diameter variation is calculated;

in the step S303, the measured crystal diameter variation is compared with the setting value of the crystal diameter variation to obtain a difference as an input variable of PID algorithm;

in the step S304, an adjustment value of a crystal growth process parameter is calculated by PID algorithm as an output variable of PID algorithm; and

in the step S305, the adjustment value of the crystal growth process parameter is added to the setting value of the crystal growth process parameter to obtain a process parameter of an actual crystal growth process, so as to ensure consistency of the crystal diameter variation and ensure the stability of crystal growth quality from different lots.

For example, the method for crystal growth control of a shouldering process according to some embodiments of the present disclosure can be implemented in an equipment, a device or a system having a memory and a processor.

The crystal growth process parameter of the shouldering process comprises a crystal pulling speed and/or a crystal pulling temperature.

Further, the different stages of the shouldering process comprise a different shouldering time or a different crystal length.

Specifically, in the step S301, the setting value of the crystal diameter variation at the different shouldering time or at the different crystal length of the shouldering process and the setting value of the crystal pulling speed and/or the crystal pulling temperature at different stages of the shouldering process are preset.

In the step S302, the crystal diameters at the different shouldering time or at the different crystal length of the shouldering process is obtained and the measured crystal diameter variation is calculated.

In the present invention, the crystal diameters at the different shouldering time or at the different crystal length of the shouldering process is obtained by the diameter measuring device. An image of a three-phase junction of the monocrystalline silicon ingot 107 and the silicon melt 105 in the crystal growth furnace can be collected by a CCD (Charge coupled Device) camera, then the image is processed by a computer, and the diameter of the monocrystalline silicon ingot 107 is obtained and fed back to the control system to control the crystal growth. Specifically, during the process of the crystal growth, a bright ring is generated at the solid-liquid interface of the monocrystalline silicon ingot 107 and the silicon melt 105 due to the release of a latent heat. The CCD camera catches an image signal of the bright ring, and converts the signal to the computer system through analog digital conversion, and processes the monocrystalline growth image by the image processing program in the computer system to obtain the measured diameter of the monocrystalline silicon ingot 107. For example, the method for obtaining the measured diameter of the monocrystalline silicon ingot 107 in accordance with the image signal caught from the CCD camera comprises: extracting the bright ring at the solid-liquid interface by the image processing program to obtain a crystal contour; fitting the crystal contour to obtain an elliptical boundary; correcting the elliptical boundary to a circular boundary; taking three pixel points on the circular boundary, taking their coordinate values into the circular coordinate formula, forming the equation and solving the solution; and calculating a center coordinate of a diameter of the crystal.

In the step S303, the measured crystal diameter variation is compared with the setting value of the crystal diameter variation at the different shouldering time or at the different crystal length of the shouldering process to obtain a difference as the input variable of PID algorithm.

It should be noted that, the measured crystal diameter variation and the setting value thereof (the setting value of the crystal diameter variation) are the values at the same stage of the shouldering process, i.e. the values at the same shouldering time or at the same crystal length.

In the step S304, the adjustment value of the crystal pulling speed or the adjustment value of the temperature is calculated by PID algorithm as the output variable of PID algorithm.

The PID algorithm is controlled according to the Proportional (P), integral (I), and derivative (D) of the deviation. Proportional control can quickly reflect the error, thus reducing the error, but the proportional control cannot eliminate the steady-state error. The addition of the proportional gain causes the system to be unstable. The function of the integral control is that as long as the system has errors, the integral control function is continuously accumulated, and a control amount is output to eliminate the error. Therefore, as long as there is enough time, the integral control will completely eliminate the error, but the integral action is too strong, the system will overshoot and even make the system oscillate; the differential control can reduce the overshoot and overcome the oscillation, and improve the stability of the system. At the same time, speed up the dynamic response of the system and reduce the adjustment time to improve the dynamic performance of the system.

Finally, in the step S305, the adjustment value of the crystal pulling speed is added to the setting value of the crystal pulling speed to obtain the crystal pulling speed of the actual crystal growth process; the adjustment value of the temperature is added to the setting value of the temperature to obtain the temperature of the actual crystal growth process.

FIG. 4 depicts a schematic view of the method for crystal growth control of the shouldering process according to some embodiments of the present disclosure. As shown in FIG. 4, the input of PID algorithm is the difference between the measured crystal diameter variation and the setting value of the crystal diameter variation; the outputs of PID algorithm are the adjustment value of the crystal pulling speed and the adjustment value of the temperature. The adjustment value of the crystal pulling speed is added to the setting value of the crystal pulling speed to obtain an actual crystal pulling speed. The adjustment value of the temperature is added to the setting value of the temperature to obtain an actual temperature.

In accordance with the method for crystal growth control of the shouldering process can compare the measured crystal diameter variation with the setting value of the crystal diameter variation to obtain the difference as the input variable of PID algorithm, calculate the adjustment value the crystal growth process parameter by PID algorithm as the output variable of PID algorithm, and control the crystal diameter change of the shouldering process by fine-turning the crystal growth process parameter to overcome an influence of small changes in the thermal field to the shouldering process, such that the repeatability of the crystal shape and shoulder shape for each growth is high to ensure the crystal diameter variation is consistent. Therefore, the repeatability of the shouldering process and the stability of the process are improve to establish the basis for the stability and the repeatability of the entire crystal growth process, so that the crystal quality of each growth is consistent.

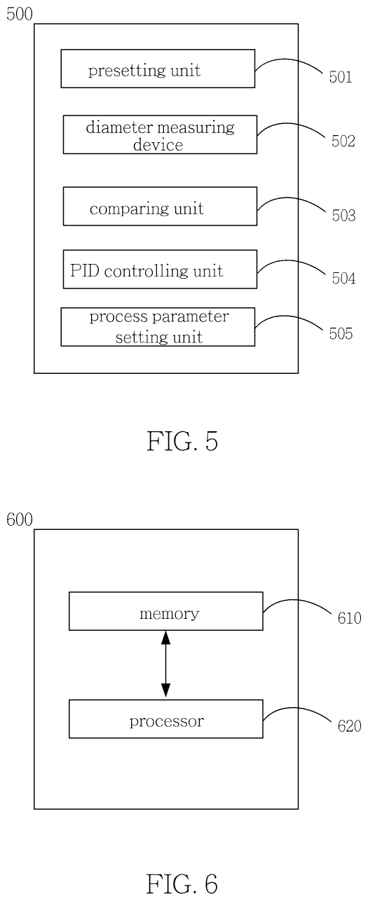

As shown in FIG. 5, the device 500 for crystal growth control of the shouldering process comprises a presetting unit 501, a diameter measuring device 502, a comparing unit 503, a PID controlling unit 504, and a process parameter setting unit 505.

The presetting unit 501 is configured to preset a setting value of a crystal diameter variation at different stages of a shouldering process and a setting value of a crystal growth process parameter at different stages of the shouldering process.

The diameter measuring device 502 is configured to obtain crystal diameters at different stages of the shouldering process and calculating a measured crystal diameter variation.

The comparing unit 503 is configured to compare the measured crystal diameter variation with the setting value of the crystal diameter variation to obtain a difference.

The PID controlling unit 504 is configured to take the difference as an input variable of the PID controlling unit and calculating an adjustment value of a crystal growth process parameter by PID algorithm as an output variable of the PID controlling unit.

The process parameter setting unit 505 is configured to add the adjustment value of the crystal growth process parameter and the setting value of the crystal growth process parameter to obtain a process parameter of an actual crystal growth process.

The crystal growth process parameter of the shouldering process comprises a crystal pulling speed and/or a crystal pulling temperature. The presetting unit 501 presets the setting value of the crystal diameter variation, the setting value of the crystal pulling speed and/or the crystal pulling temperature at a different shouldering time or at a different crystal length of a shouldering process. The PID controlling unit 504 takes the difference obtained from the comparing unit 503 as an input variable of the PID controlling unit, and calculates an adjustment value of the crystal pulling speed and/or the crystal pulling temperature by PID algorithm as an output variable of the PID controlling unit. The process parameter setting unit 505 adds the adjustment value of the crystal pulling speed and the setting value of the crystal pulling speed to obtain the crystal pulling speed of an actual crystal growth process, and adds the adjustment value of the temperature and the setting value of the temperature to obtain the temperature of the actual crystal growth process.

Further, the different stages of the shouldering process include a different shouldering time or a different crystal length. The crystal diameter and variation the setting value thereof (the setting value of the crystal diameter variation) are the values at the same stage of the shouldering process, i.e. the values at the same shouldering time or at the same crystal length.

For example, the diameter measuring device 502 is a CCD camera. An image of a three-phase junction of the monocrystalline silicon ingot 107 and the silicon melt 105 in the crystal growth furnace can be collected by the CCD camera, then the image is processed by a computer, and the diameter of the monocrystalline silicon ingot 107 is obtained and fed back to the control system to control the crystal growth. Specifically, during the process of the crystal growth, a bright ring is generated at the solid-liquid interface of the monocrystalline silicon ingot 107 and the silicon melt 105 due to the release of a latent heat. The CCD camera catches an image signal of the bright ring, and converts the signal to the computer system through analog digital conversion, and processes the monocrystalline growth image by the image processing program in the computer system to obtain the measured diameter of the monocrystalline silicon ingot 107. For example, the method for obtaining the measured diameter of the monocrystalline silicon ingot 107 in accordance with the image signal caught from the CCD camera comprises: extracting the bright ring at the solid-liquid interface by the image processing program to obtain a crystal contour; fitting the crystal contour to obtain an elliptical boundary; correcting the elliptical boundary to a circular boundary; taking three pixel points on the circular boundary, taking their coordinate values into the circular coordinate formula, forming the equation and solving the solution; and calculating a center coordinate of a diameter of the crystal.

FIG. 6 depicts a schematic block diagram of a system 600 for crystal growth control of the shouldering process according to some embodiments of the present disclosure. The system 600 comprises a memory 610 and a processor 620.

The memory 610 stores a program code for executing the steps of method for crystal growth control of the shouldering process according to some embodiments of the present disclosure.

The processor 620 is configured to execute the program code stored in the memory 610 to execute the steps of method for crystal growth control of the shouldering process according to some embodiments of the present disclosure, and execute the presetting unit 501, the diameter measuring device 502, the comparing unit 503, the PID controlling unit 504 and the process parameter setting unit 505 in the device for crystal growth control of the shouldering process according to some embodiments of the present disclosure.

In one embodiment, the program code is operated by the processor 620 to execute the method for crystal growth control of the shouldering process.

Moreover, in accordance with the embodiment of the present disclosure, a computer storage medium is provided, a program instruction is stored at the computer storage medium. The program instruction is operated by a computer or a processor to execute the steps of the method for crystal growth control of the shouldering process according to some embodiments of the present disclosure, and execute the units in the device for crystal growth control of the shouldering process according to some embodiments of the present disclosure. The storage medium may comprise, for example, a memory component of a tablet computer, a hard disk of a personal computer, a read only memory (ROM), an erasable programmable read only memory (EPROM), and a Compact disc read only memory (CD-ROM), USB memory, or any combination of the above storage media. The computer readable storage medium can be any combination of one or more computer readable storage media. For example, a computer readable storage medium includes computer readable code for randomly generating a sequence of action instructions, and another computer readable storage medium containing computer readable code for performing crystal growth control of the shouldering process.

In one embodiment, the program instruction is operated by the computer can execute the units in the device for crystal growth control of the shouldering process according to some embodiments of the present disclosure, and execute the steps of the method for crystal growth control of the shouldering process according to some embodiments of the present disclosure.

In one embodiment, the program instruction is operated by the computer can execute the method for crystal growth control of the shouldering process.

Above all, the method, device, system, and computer storage medium for crystal growth control of a shouldering process according to the present disclosure can control the diameter change of the shouldering process by PID algorithm, and control the crystal diameter change of the shouldering process by fine-turning the crystal growth process parameter to overcome an influence of small changes in the thermal field to the shouldering process, such that the repeatability of the crystal shape and shoulder shape for each growth is high to ensure the crystal diameter variation is consistent. Therefore, the repeatability of the shouldering process and the stability of the process are improve to establish the basis for the stability and the repeatability of the entire crystal growth process, so that the crystal quality of each growth is consistent.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantage.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A method for crystal growth control of a shouldering process, comprising the steps of:
presetting a setting value of a crystal diameter variation at different stages of a shouldering process and a setting value of a crystal growth process parameter at different stages of the shouldering process;
obtaining crystal diameters at different stages of the shouldering process and calculating a measured crystal diameter variation;
comparing the measured crystal diameter variation with the setting value of the crystal diameter variation to obtain a difference as an input variable of PID algorithm;
calculating an adjustment value of a crystal growth process parameter by PID algorithm as an output variable of PID algorithm; and
adding the adjustment value of the crystal growth process parameter and the setting value of the crystal growth process parameter to obtain a process parameter of an actual crystal growth process, so as to ensure consistency of the crystal diameter variation and ensure the stability of crystal growth quality from different lots.

2. The method according to claim 1, wherein the crystal growth process parameter of the shouldering process comprises a crystal pulling speed and/or a temperature.

3. The method according to claim 1, wherein the different stages of the shouldering process comprise a different shouldering time.

4. The method according to claim 1, wherein the different stages of the shouldering process comprise a different crystal length.

5. The method according to claim 1, wherein the crystal diameters at different stages of the shouldering process is obtained by a diameter measuring device.

6. A device for crystal growth control of a shouldering process, comprising:
a presetting unit for presetting a setting value of a crystal diameter variation at different stages of a shouldering process and a setting value of a crystal growth process parameter at different stages of the shouldering process;
a diameter measuring device for obtaining crystal diameters at different stages of the shouldering process and calculating a measured crystal diameter variation;
a comparing unit for comparing the measured crystal diameter variation with the setting value of the crystal diameter variation to obtain a difference;
a PID controlling unit for taking the difference as an input variable of the PID controlling unit and calculating an adjustment value of a crystal growth process parameter by PID algorithm as an output variable of the PID controlling unit; and
a process parameter setting unit for adding the adjustment value of the crystal growth process parameter and the setting value of the crystal growth process parameter to obtain a process parameter of an actual crystal growth process.

7. The device according to claim 6, wherein the crystal growth process parameter of the shouldering process includes a crystal pulling speed and/or a temperature.

8. The device according to claim 6, wherein the different stages of the shouldering process comprise a different shouldering time or a different crystal length.

9. A system for crystal growth control of a shouldering process, comprising: a memory, a processor and a computer program stored on the memory and operated on the processor, wherein the processor executes the steps of method in claim 1 when operating the computer program.

10. A computer storage medium, storing a computer program, wherein the computer storage medium executes the steps of method in claim 1 when operating the computer program.
